(19) United States
(12) Patent Application Publication
(10) Pub. No.: US 2026/0022463 A1
(43) Pub. Date: Jan. 22, 2026

(54) FILM FORMING METHOD AND FILM FORMING APPARATUS

(71) Applicant: Tokyo Electron Limited, Tokyo (JP)

(72) Inventor: Hiroki MURAKAMI, Yamanashi (JP)

(21) Appl. No.: 19/245,806

(22) Filed: Jun. 23, 2025

(30) Foreign Application Priority Data
Jul. 16, 2024 (JP) 2024-113554

(51) Int. Cl. C23C 16/455; C23C 16/28; C23C 16/34; C23C 16/52

(52) U.S. Cl. CPC C23C 16/4557; C23C 16/28; C23C 16/342; C23C 16/52

(57) ABSTRACT

A film forming method includes the steps of loading a plurality of substrates into a processing chamber, heating an inside of the processing chamber by a chamber heater provided around the processing chamber, and heating a source gas in a first gas nozzle by a gas heater included in the first gas nozzle, and supplying the heated source gas from the first gas nozzle into the processing chamber. The supplying the source gas includes changing a position where the source gas is activated.

### CROSS-REFERENCE TO RELATED APPLICATIONS

This application is based upon and claims priority to Japanese Patent Application No. 2024-113554, filed on Jul. 16, 2024, the entire contents of which are incorporated herein by reference.

### BACKGROUND

### 1. Field of the Invention

The present disclosure relates to film forming methods, and film forming apparatuses. The film forming method may sometimes be referred to as a film deposition method. The film forming apparatus may sometimes be referred to as a film deposition apparatus.

### 2. Description of the Related Art

There is a proposed technique which forms a seed layer on different underlayers before forming a boron nitride film to ensure a uniform incubation time, so as to deposit a uniform boron nitride film on the different underlayers.

Japanese Laid-Open Patent Publication No. 2022-114918 is an example of the related art.

### SUMMARY

One object of the present disclosure is to provide a technique capable of controlling an in-plane distribution of a deposited film.

According to an aspect of the present disclosure, a film forming method includes loading a plurality of substrates into a processing chamber; heating an inside of the processing chamber by a chamber heater provided around the processing chamber; and heating a source gas in a first gas nozzle by a gas heater included in the first gas nozzle, and supplying the heated source gas from the first gas nozzle into the processing chamber, wherein the supplying the source gas includes changing a position where the source gas is activated.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a vertical sectional view illustrating a film forming apparatus according to an embodiment;

FIG. 2 is a horizontal cross sectional view illustrating the film forming apparatus according to the embodiment;

FIG. 3 is a cross sectional view illustrating an example of a gas nozzle provided in the film forming apparatus according to the embodiment;

FIG. 4 is a timing chart illustrating a film forming method according to a first example of the embodiment;

FIG. 5 is a timing chart illustrating the film forming method according to a second example of the embodiment;

FIG. 6 is a diagram illustrating measurement results of a film deposition rate of a boron film; and

FIG. 7 is a diagram illustrating measurement results of an in-plane distribution of a thickness of the boron film.

### DETAILED DESCRIPTION

Hereinafter, non-limiting exemplary embodiments of the present disclosure will be described with reference to the accompanying drawings. In all of the accompanying drawings, the same or corresponding members or parts are designated by the same or corresponding reference numerals, and a redundant description thereof will be omitted.

### [Film Forming Apparatus]

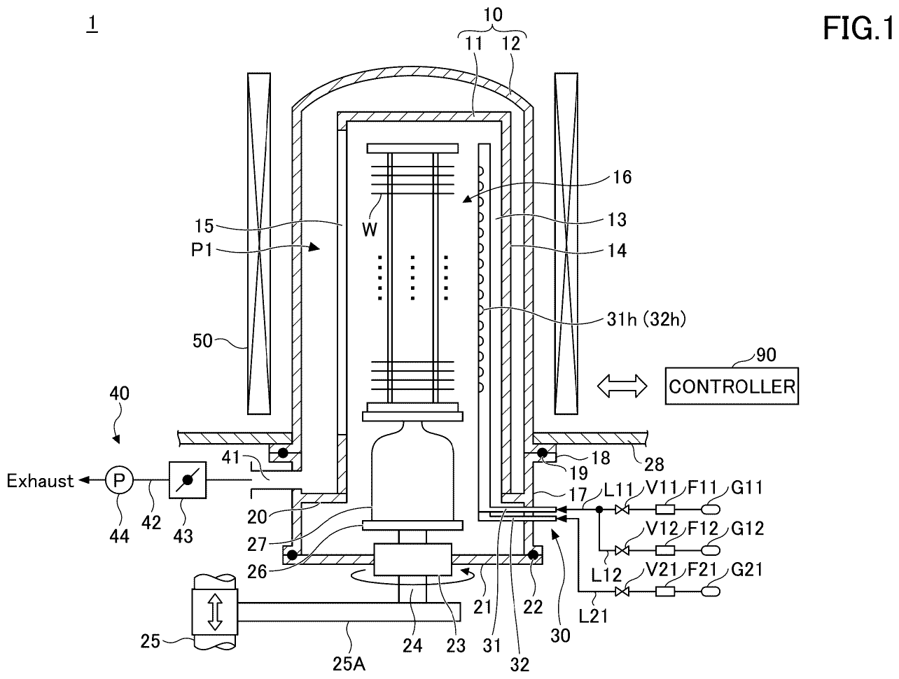

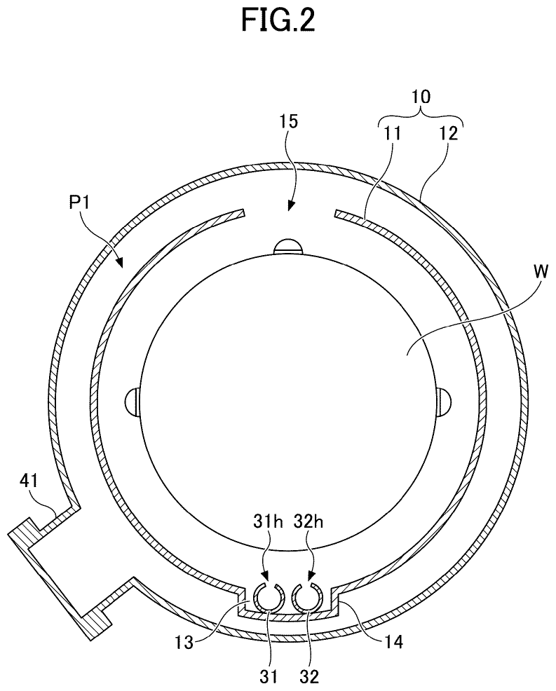

A film forming apparatus 1 according to an embodiment will be described, with reference to FIG. 1 and FIG. 2. FIG. 1 is a vertical cross sectional view illustrating the film forming apparatus 1 according to the embodiment. FIG. 2 is a horizontal cross sectional view illustrating the film forming apparatus 1 according to the embodiment.

The film forming apparatus 1 is a batch type apparatus that performs a process on a plurality of substrates W simultaneously in a single processing cycle. The substrates W are semiconductor wafers, for example. The film forming apparatus 1 includes a processing chamber 10, a gas supply 30, an exhaust 40, a chamber heater 50, and a controller (or a control device) 90.

The inside of the processing chamber 10 can be depressurized. The processing chamber 10 accommodates the substrates W. The processing chamber 10 includes an inner tube 11 and an outer tube 12. The inner tube 11 has a cylindrical shape with a ceiling and an open lower end. The outer tube 12 has a cylindrical shape with a ceiling and an open lower end, and covers an outer side of the inner tube 11. The inner tube 11 and the outer tube 12 are formed of a heat resistant material, such as quartz or the like. The inner tube 11 and the outer tube 12 have a coaxially arranged double tube structure.

A housing 13 that houses a gas supply pipe is formed on a sidewall of the inner tube 11 along a longitudinal direction (a vertical direction). For example, a portion of the sidewall of the inner tube 11 may protrude outward to form a protrusion 14, and the inside of the protrusion 14 may form the housing 13.

A rectangular opening 15 is formed in the sidewall of the inner tube 11 along the longitudinal direction. The opening 15 opposes the housing 13.

The opening 15 is a gas exhaust port formed so as to exhaust the gas inside the inner tube 11. A length of the opening 15 is the same as a length of a boat 16, or is longer than the length of the boat 16, and is formed to extend in the vertical direction.

A lower end of the processing chamber 10 is supported by a cylindrical manifold 17. The manifold 17 is formed of stainless steel, for example. A flange 18 is formed at an upper end of the manifold 17. The flange 18 supports the lower end of the outer tube 12. A seal member 19, such as an O-ring or the like, is provided between the flange 18 and the lower end of the outer tube 12. Thus, the inside of the outer tube 12 is maintained airtight.

An annular support 20 is provided on an inner wall of an upper portion of the manifold 17. The annular support 20 supports the lower end of the inner tube 11. A lid 21 is airtightly attached to an opening at a lower end of the manifold 17 via a seal member 22, such as an O-ring or the like. Accordingly, the opening at the lower end of the processing chamber 10, that is, the opening of the manifold 17 is airtightly closed. The lid 21 is formed of stainless steel, for example.

A rotary shaft 24 penetrates a central portion of the lid 21 via a magnetic fluid seal 23. A lower portion of the rotary shaft 24 is rotatably supported on an arm 25A of an elevator mechanism 25 including a boat elevator.

A rotating plate 26 is provided on an upper end of the rotary shaft 24. The boat 16, which holds the substrates W via a quartz heat insulating stage 27, is placed on the rotating plate 26. The boat 16 is rotated by rotating the rotary shaft 24. The boat 16 is moved up and down integrally with the lid 21, by causing the elevator mechanism 25 to move up and down. Accordingly, the boat 16 is inserted into and removed from the processing chamber 10. The boat 16 can be accommodated inside the processing chamber 10. The boat 16 holds the plurality of substrates W (for example, 50 to 150 substrates W) in a rack configuration (or a tiered arrangement). The boat 16 holds the plurality of substrates W substantially horizontally with a gap in the vertical direction between two adjacent substrates W.

The gas supply 30 supplies various gases into the inner tube 11. The gas supply 30 includes a gas nozzle 31, and a gas nozzle 32. The gas nozzle 31 is an example of a first gas nozzle. The gas nozzle 32 is an example of a second gas nozzle. The gas nozzles 31 and 32 are formed of quartz, for example. The gas supply 30 may further include another gas nozzle.

The gas nozzle 31 is fixed to the manifold 17. The gas nozzle 31 extends linearly along the vertical direction at a position near the inner tube 11, bends in an L-shape inside the manifold 17 to extend in the horizontal direction, and penetrates the manifold 17. A plurality of gas holes 31h are provided in a portion of the gas nozzle 31 located inside the inner tube 11. The gas holes 31h are provided at predetermined intervals along the vertical direction. Each gas hole 31h discharges the gas horizontally toward the substrate W from an outer side in a radial direction of the substrate W. Each gas hole 31h discharges the gas parallel to a principal surface of the substrate W.

A supply path L11 is connected to the gas nozzle 31. The supply path L11 is provided with a supply source G11 of a source gas, a mass flow controller F11, and a valve V11 in this order from an upstream side to a downstream side in the gas flow direction. The source gas includes triethylborane (TEB). Triethylborane is an example of the source gas. A supply timing of the source gas from the supply source G11 is controlled by the valve V11, and a flow rate of the source gas is adjusted to a predetermined flow rate by the mass flow controller F11. The source gas flows into the gas nozzle 31 from the supply path L11, and is discharged into the inner tube 11 from the plurality of gas holes 31h.

A supply path L12 is connected to a downstream side of the valve V11 of the supply path L11. The supply path L12 is provided with a supply source G12 of a purge gas, a mass flow controller F12, and a valve V12 in this order from an upstream side to a downstream side in a gas flow direction. The purge gas includes nitrogen (N₂). A supply timing of the purge gas from the source G12 is controlled by the valve V12, and a flow rate of the purge gas is adjusted to a predetermined flow rate by the mass flow controller F12. The purge gas flows into the gas nozzle 31 from the supply path L12, and is discharged into the inner tube 11 from the plurality of gas holes 31h.

The gas nozzle 32 is fixed to the manifold 17. The gas nozzle 32 extends linearly along the vertical direction at a position near the inner tube 11, bends in an L-shape inside the manifold 17 to extend in the horizontal direction, and penetrates the manifold 17. The gas nozzle 32 is provided side by side with the gas nozzle 31 in a circumferential direction of the inner tube 11. A plurality of gas holes 32h are provided in a portion of the gas nozzle 32 located inside the inner tube 11. The gas holes 32h are provided at predetermined intervals along the vertical direction. Each gas hole 32h discharges the gas horizontally toward the substrate W from the outer side in the radial direction of the substrate W. Each gas hole 32h discharges the gas parallel to the principal surface of the substrate W.

A supply path L21 is connected to the gas nozzle 32. The supply path L21 is provided with a supply source G21 of a reactive gas, a mass flow controller F21, and a valve V21 in this order from an upstream side to a downstream side in a gas flow direction. The reactive gas includes ammonia (NH₃). Ammonia is an example of the reactive gas. A supply timing of the reactive gas from the supply source G21 is controlled by the valve V21, and a flow rate of the reactive gas is adjusted to a predetermined flow rate by the mass flow controller F21. The reactive gas flows into the gas nozzle 32 from the supply path L21, and is discharged into the inner tube 11 from the plurality of gas holes 32h.

The exhaust 40 exhausts the gas that is discharged from the inside of the inner tube 11 through the opening 15, and is discharged from a gas outlet 41 through a space P1 between the inner tube 11 and the outer tube 12. The gas outlet 41 is formed in an upper sidewall of the manifold 17 at a position above the annular support 20. An exhaust flow path 42 is connected to the gas outlet 41. A pressure control valve 43 and a vacuum pump 44 are successively provided in the exhaust flow path 42, so that the inside of the processing chamber 10 can be exhausted.

The chamber heater 50 is provided around the outer tube 12. The chamber heater 50 is provided on the base plate 28, for example. The chamber heater 50 has a cylindrical shape so as to cover the outer tube 12. The chamber heater 50 includes a heating element, for example, and heats the inside of the processing chamber 10 and each substrate W inside the processing chamber 10.

The controller 90 may be electronic circuitry (including a processor), such as a central processing unit (CPU), a field programmable gate array (FPGA), an application specific integrated circuit (ASIC), or the like. The electronic circuitry performs the processes of the controller 90 described in the present specification by executing instruction codes or command codes stored in a memory, or by being designed for specialized circuit applications or specific purposes.

### [Gas Nozzle]

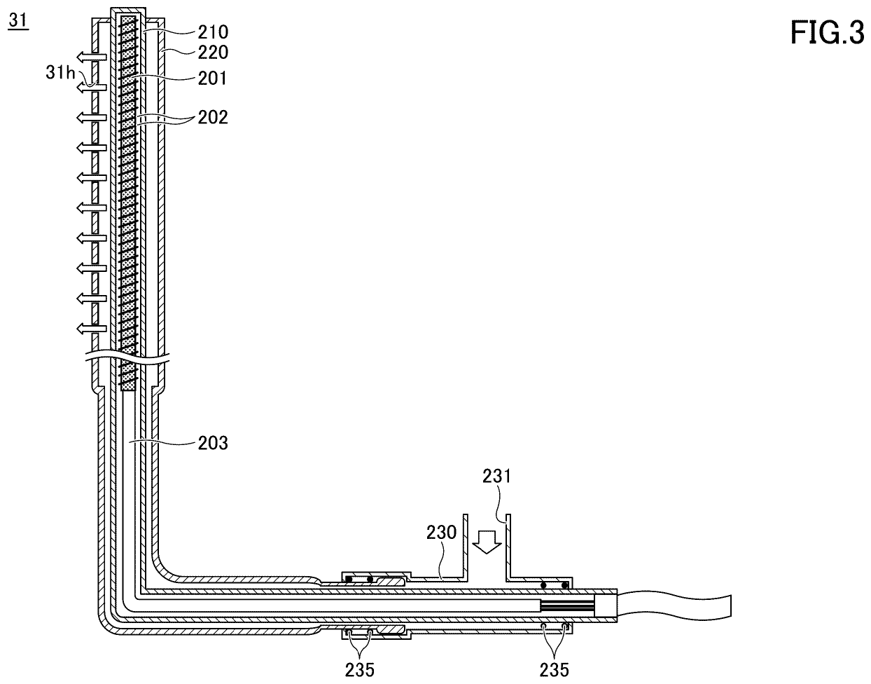

An example of the gas nozzle 31 included in the film forming apparatus 1 will be described with reference to FIG. 3. FIG. 3 is a cross sectional view illustrating the example of the gas nozzle 31 included in the film forming apparatus 1 according to the embodiment.

The gas nozzle 31 includes an inner pipe 210, an outer pipe 220, and an adapter 230. The outer pipe 220 and the adapter 230 are connected via a seal 235. The inner pipe 210 is disposed inside the outer pipe 220 and the adapter 230. An alumina core 201, a heating element 202, and a flexible cable 203 are provided inside the inner pipe 210. The heating element 202 is wound around the alumina core 201. The flexible cable 203 connects the heating element 202 and a heater power supply (not illustrated). The heater power supply supplies power to the heating element 202 via the flexible cable 203. As a result, the heating element 202 generates heat, thereby heating the alumina core 201.

The source gas supplied from a supply port 231 of the adapter 230 passes through a space between the inner pipe 210 and the adapter 230 and a space between the inner pipe 210 and the outer pipe 220, and is discharged from the gas holes 31h. Further, the source gas is heated by supplying power from the heater power source to the heating element 202, and the heated source gas is discharged from the gas holes 31h. As described above, the gas nozzle 31 includes the outer pipe 220 through which the source gas flows, and the gas heater disposed inside the outer pipe 220 to heat the source gas flowing through the outer pipe 220. The gas heater includes the alumina core 201, and the heating element 202. The gas heater is disposed inside the outer pipe 220 that is disposed inside the inner tube 11.

### Film Forming Method

### First Example

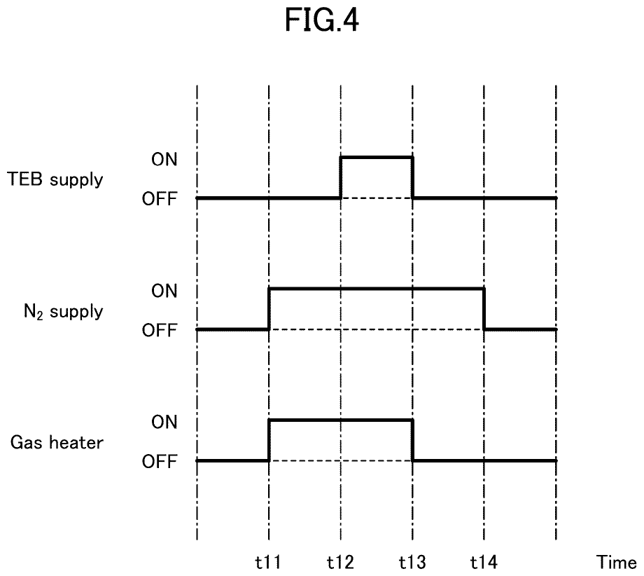

A film forming method according to a first example of the embodiment will be described with reference to FIG. 4. FIG. 4 is a timing chart illustrating a film forming method according to the first example of the embodiment. The film forming method according to the first example is a method of forming a boron film by chemical vapor deposition (CVD) in which triethylborane is supplied. The film forming method according to the first example is performed under a control of the controller 90.

First, the controller 90 raises the arm 25A to load the boat 16 holding the plurality of substrates W into the processing chamber 10, and closes the opening at the lower end of the processing chamber 10 airtight by the lid 21. Next, the controller 90 controls the exhaust 40 so that the inside of the processing chamber 10 becomes a set pressure, and controls the chamber heater 50 so that the inside of the processing chamber 10 becomes a predetermined temperature. A set temperature of the chamber heater 50 is higher than a thermal decomposition temperature of triethylborane, for example.

Next, the controller 90 performs a film forming process of forming a boron film on a surface of each substrate W inside the processing chamber 10 by chemical vapor deposition in which triethylborane is supplied.

At a time t11, the gas nozzle 31 starts supplying the nitrogen into the inner tube 11. At the time t11, the gas heater starts heating the gas nozzle 31. The supplying of the nitrogen from the gas nozzle 31 into the inner tube 11 continues until a time t14. The heating of the gas nozzle 31 continues until a time t13.

At a time t12, the gas nozzle 31 starts supplying the triethylborane into the inner tube 11. Thus, a boron film is formed on each substrate W. In this state, because the gas nozzle 31 is continuously heated by the gas heater, the triethylborane is heated in the gas nozzle 31 and supplied into the inner tube 11. The triethylborane has a high reactivity by being heated in the gas nozzle 31. Accordingly, a position where the triethylborane is activated changes from the inside of the inner tube 11 to the inside of the inner tube 11 and the inside of the gas nozzle 31. For this reason, the inside of the inner tube 11 changes from a supply rate-limiting state to a reaction rate-limiting state, and the amount of the boron film deposited at the central portion of each substrate W increases. As a result, a boron film having a high in-plane uniformity of the thickness can be formed on each substrate W. That is, the in-plane distribution of the deposited boron film can be controlled. A set temperature of the gas heater is higher than the set temperature of the chamber heater 50, for example. In this case, the reactivity of the triethylborane tends to become high in the gas nozzle 31.

At the time t13, the gas nozzle 31 stops supplying the triethylborane into the inner tube 11. At the time t13, the gas heater stops heating the gas nozzle 31. During a period from the time t13 to the time t14, the supplying of the nitrogen from the gas nozzle 31 into the inner tube 11 continues. For this reason, the triethylborane remaining inside the inner tube 11 is replaced with the nitrogen. That is, the inside of the inner tube 11 is purged.

At the time t14, the gas nozzle 31 stops supplying the nitrogen into the inner tube 11.

Next, the controller 90 raises the pressure inside the processing chamber 10 to atmospheric pressure, and lowers the temperature inside the processing chamber 10 to a substrate unloading temperature, before lowering the arm 25A to unload the boat 16 from inside the processing chamber 10. The film forming process with respect to the plurality of substrates W is completed by the processes described above.

According to the film forming method of the first example, the triethylborane heated by the gas heater is supplied from the gas nozzle 31 into the processing chamber 10 in a state where the inside of the inner tube 11 is heated by the chamber heater 50. Because the triethylborane is heated in the gas nozzle 31, the reactivity of the triethylborane becomes high. Accordingly, the position where the triethylborane is activated changes from the inside of the inner tube 11 to the inside of the inner tube 11 and the inside of the gas nozzle 31. For this reason, the inside of the inner tube 11 changes from the supply rate-limiting state to the reaction rate-limiting state, and the amount of the boron film deposited at the central portion of each substrate W increases. As a result, a boron film having a high in-plane uniformity of the thickness can be formed on each substrate W. That is, the in-plane distribution of the deposited boron film can be controlled.

In the example illustrated in FIG. 4, the gas nozzle 31 is heated by the gas heater during the period from the time t11 to the time t13, but the timing at which the gas nozzle 31 is heated by the gas heater is not limited thereto. For example, the gas nozzle 31 may be heated by the gas heater at the same timing as the timing at which the gas nozzle 31 supplies the triethylborane into the inner tube 11. That is, the gas nozzle 31 may be heated by the gas heater during the period from the time t12 to the time t13.

### Second Example

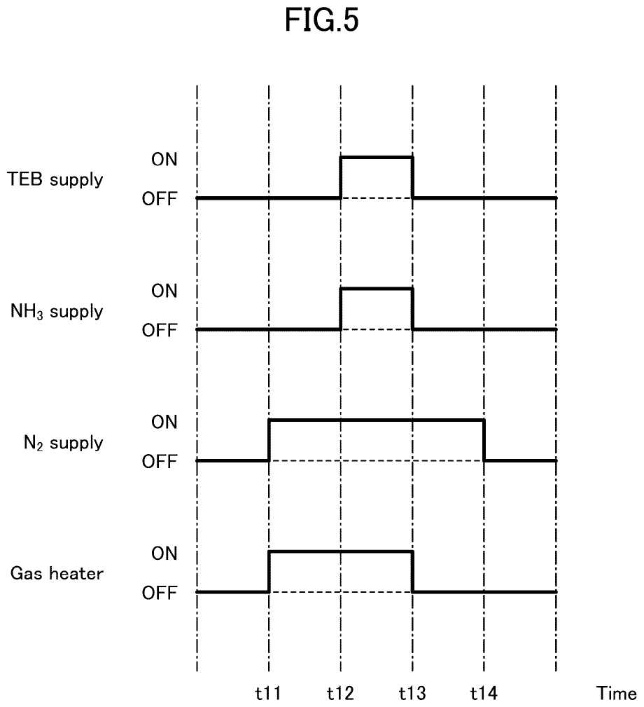

The film forming method according to a second example of the embodiment will be described with reference to FIG. 5. FIG. 5 is a timing chart illustrating the film forming method according to the second example of the embodiment. The film forming method according to the second example differs from the film forming method according to the first example in that a configuration of the second example supplies ammonia simultaneously with triethylborane. The configuration of the second example of the film forming method is otherwise the same as that of the first example of the film forming method. That is, the second example of the film forming method forms a boron nitride film by chemical vapor deposition in which triethylborane and ammonia are simultaneously supplied.

According to second example of the film forming method, in a state where the inside of the inner tube 11 is heated by the chamber heater 50, the triethylborane heated by the gas heater is supplied from the gas nozzle 31 into the processing chamber 10. Because the triethylborane is heated in the gas nozzle 31, the reactivity of the triethylborane becomes high. Accordingly, the position where the triethylborane is activated changes from the inside of the inner tube 11 to the inside of the inner tube 11 and the inside of the gas nozzle 31. For this reason, the inside of the inner tube 11 changes from a supply rate-limiting state to a reaction rate-limiting state, and an amount of the boron nitride film deposited at the central portion of each substrate W increases. As a result, a boron nitride film having a high in-plane uniformity of the thickness can be formed on each substrate W. That is, the in-plane distribution of the deposited boron nitride film can be controlled.

In the example illustrated in FIG. 5, the gas nozzle 31 is heated by the gas heater during the period from the time t11 to the time t13, but the timing at which the gas nozzle 31 is heated by the gas heater is not limited thereto. For example, the gas nozzle 31 may be heated by the gas heater at the same timing as the timing at which the gas nozzle 31 supplies the triethylborane and the ammonia into the inner tube 11. That is, the gas nozzle 31 may be heated by the gas heater during the period from the time t12 to the time t13.

### Experimental Results

In experiments, the film forming apparatus 1 according to the embodiment was used to form a boron film by performing the film forming method illustrated in the timing chart of FIG. 4 under the following condition A, and a film deposition rate of the boron film and the in-plane distribution of the thickness of the boron film were measured.

### <Condition A>

Triethylborane supply time (a time from the time t12 to the time t13): 60 seconds
Pressure inside the processing chamber 10: 40 Pa (0.3 Torr)
Set temperature of the chamber heater 50: 300° C. to 450° C.
Set temperature of the gas heater: 800° C.

For comparative purposes, a boron film was formed under a condition (condition X) in which the gas nozzle 31 is not heated by the gas heater, and the deposition rate of the boron film and the in-plane distribution of the thickness of the boron film were measured.

### <Condition X>

Triethylborane supply time: 60 seconds
Pressure inside the processing chamber 10: 40 Pa (0.3 Torr)
Set temperature of the chamber heater 50: 300° C. to 450° C.
Set temperature of the gas heater: OFF

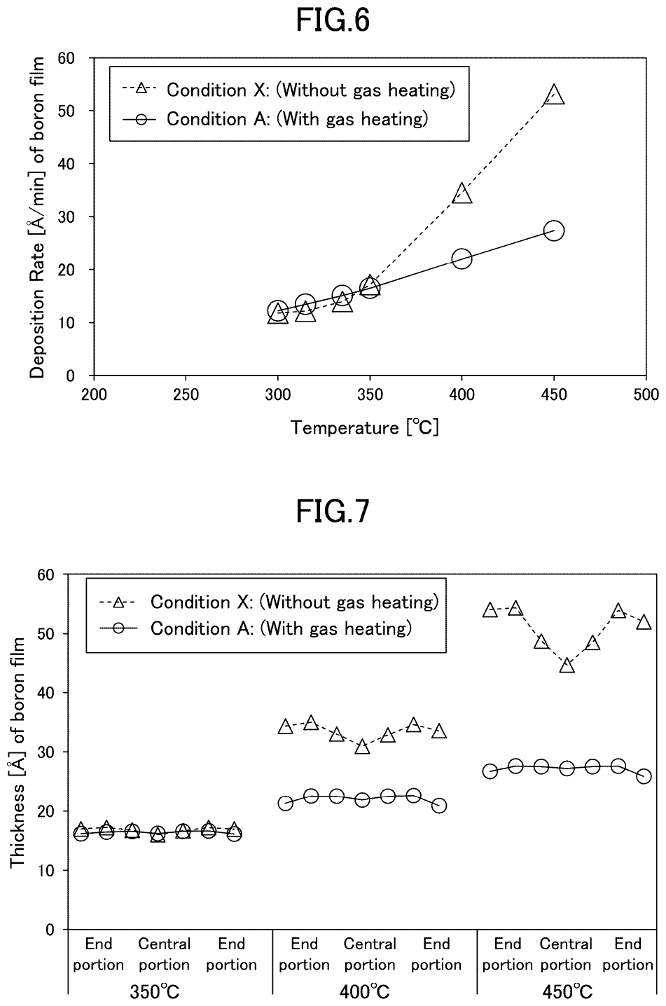

FIG. 6 is a diagram illustrating the measurement results of the film deposition rate of the boron film. In FIG. 6, the abscissa indicates the set temperature [° C.] of the chamber heater 50, and the ordinate indicates the film deposition rate [Å/min] of the boron film.

As illustrated in FIG. 6, when the set temperature of the chamber heater 50 is 350° C. or lower, there is almost no difference in the film deposition rate of the boron film between the condition A and the condition X. On the other hand, when the set temperature of the chamber heater 50 is 400° C. or higher, a difference in the film deposition rate of the boron film can be observed between the condition A and the condition X.

FIG. 7 is a diagram illustrating the measurement results of the in-plane distribution of the thickness of the boron film. FIG. 7 illustrates the in-plane distribution of the thickness [A] of the boron film for cases where the set temperature of the chamber heater 50 is 350° C., 400° C., and 450° C. In FIG. 7, circular marks indicate the in-plane distribution of the thickness of the boron film for the cases under the condition A, and triangular marks indicates the in-plane distribution of the thickness of the boron film for the cases under the condition X.

As illustrated in FIG. 7, in the case where the set temperature of the chamber heater 50 is 350° C., there is almost no difference in the in-plane distribution of the thickness of the boron film between the condition A and the condition X. As illustrated in FIG. 7, in the cases where the set temperature of the chamber heater 50 is 400° C. and 450° C., the in-plane uniformity of the thickness of the boron film is higher under the condition A than under the condition X. From these results, it was found that a boron film having a high in-plane uniformity of the thickness can be formed regardless of the set temperature of the chamber heater 50, by using the triethylborane heated in the gas nozzle 31 by the gas heater.

The embodiments disclosed herein are to be considered in all respects as illustrative only and non-limiting. The embodiments described above may be omitted, replaced, or modified in various forms without departing from the scope and spirit of the present disclosure.

In the embodiment described above, the case where the source gas is triethylborane is described, but the present disclosure is not limited thereto. The source gas is a boron-containing gas, for example. The boron-containing gas may be diborane (B₂H₆), trichlorosilane (BCl₃), trimethylborane (TMB), triethylborane, dimethylaminoborane (DMAB), or a combination thereof. The source gas may be a silicon-containing gas. The silicon-containing gas is aminosilane, silane hydride, or halogen-containing silicon, for example. The aminosilane may be diisopropylaminosilane (DIPAS), tris(dimethylamino) silane (3DMAS), bis(tert-butylamino) silane (BTBAS), or a combination thereof. The silane hydride may be monosilane (SiH₄), disilane (Si₂H₆), trisilane (Si₃H₈), tetrasilane (Si₄H₁₀), or a combination thereof. The halogen-containing silicon may be fluorine-containing silicon such as SiF₄, SiHF₃, SiH—F₂, SiH₃F, or the like, chlorine-containing silicon such as SiCl₄, SiHCl₃, or the like, bromine-containing silicon such as SiHBr₃, SiBr₄, SiH₂Br₂, SiH₂Cl₂, Si₂Cl₆, SiH₃Br, SiH₃Cl, or the like, or a combination thereof.

In the embodiment described above, the case where the reactive gas is ammonia is described, but the present disclosure is not limited thereto. The reactive gas is a gas that reacts with the source gas to generate a reaction product. The reactive gas is a nitriding gas, for example. The nitriding gas may be ammonia, diazene (N₂H₂), hydrazine (N₂H₄), monomethylhydrazine (CH₃ (NH) NH₂), or a combination thereof. The reactive gas may be an oxidizing gas. The oxidizing gas may be ozone (O₃), oxygen (O₂), water vapor (H₂O), nitrogen dioxide (NO₂), or a combination thereof.

According to the present disclosure, it is possible to control the in-plane distribution of the deposited film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
loading a plurality of substrates into a processing chamber;
heating an inside of the processing chamber by a chamber heater provided around the processing chamber; and
heating a source gas in a first gas nozzle by a gas heater included in the first gas nozzle, and supplying the heated source gas from the first gas nozzle into the processing chamber,
wherein the supplying the source gas includes changing a position where the source gas is activated.

2. The film forming method as claimed in claim 1, wherein the supplying the source gas includes supplying the source gas parallel to principal surfaces of the plurality of substrates.

3. The film forming method as claimed in claim 1, wherein the supplying the source gas includes activating at least a portion of the source gas in the first gas nozzle.

4. The film forming method as claimed in claim 1, wherein a set temperature of the gas heater is higher than a set temperature of the chamber heater.

5. The film forming method as claimed in claim 1, wherein a set temperature of the chamber heater is higher than a thermal decomposition temperature of the source gas.

6. The film forming method as claimed in claim 1, wherein the source gas is a silicon-containing gas or a boron-containing gas.

7. The film forming method as claimed in claim 1, further comprising:
supplying a reactive gas, which is to react with the source gas, from a second gas nozzle into the processing chamber; and
simultaneously performing the supplying the source gas and the supplying the reactive gas.

8. The film forming method as claimed in claim 7, wherein the reactive gas is an oxidizing gas or a nitriding gas.

9. A film forming apparatus comprising:
a processing chamber configured to accommodate a plurality of substrates;
a chamber heater provided around the processing chamber and configured to heat an inside of the processing chamber;
a first gas nozzle configured to supply a source gas into the processing chamber; and
a controller, wherein:
the first gas nozzle includes a gas heater configured to heat the source gas in the first gas nozzle,
the controller performs a process including:
loading the plurality of substrates into the processing chamber;
heating the inside of the processing chamber by the chamber heater; and
heating the source gas in the first gas nozzle by the gas heater, and supplying the heated source gas into the processing chamber by the first gas nozzle, and
the supplying the source gas includes changing a position where the source gas is activated.
